(19) United States
(12) Patent Application Publication
(10) Pub. No.: US 2002/0130376 A1
(43) Pub. Date: Sep. 19, 2002

(54) Method to reduce transistor channel length using SDOX

(76) Inventors: Zhongze Wang, Boise, ID (US); Jigish D. Trivedi, Boise, ID (US); Manoj Patel, Boise, ID (US)

Correspondence Address: SCHWEGMAN, LUNDBERG, WOESSNER & KLUTH, P.A., P.O. BOX 2938, MINNEAPOLIS, MN, 55402, US

(21) Appl. No.: 09/810,005

(22) Filed: Mar. 16, 2001

(51) Int. Cl. H01L 29/76; H01L 29/94

(52) U.S. Cl. 257/408

(57) ABSTRACT

An improved method of reducing transistor channel length is shown. The physical channel length is reduced below a length set by the minimum lithographic feature size by implanting source/drain region extensions. The physical gate width is then narrowed by oxidizing the walls of the gate. The combination of narrowing the physical channel length and narrowing the physical gate width results in an effective channel length L_{eff} that is more narrow than possible using lithography alone. The negative side effects of increasing effective gate thickness are eliminated through the use of a barrier layer.

### FIELD OF THE INVENTION

The invention relates to the fabrication of semiconductor devices, such as dynamic random access memory devices, and more particularly to patterning and fabrication of gates and channels in transistor devices.

### BACKGROUND OF THE INVENTION

In high performance transistor devices such as dynamic random access memory (DRAM) or static random access memory (SRAM) there is ever increasing pressure to make smaller and faster operating transistors. One approach in this effort has been a continual reduction in channel length of transistors. A shorter channel length yields a smaller device with faster operation.

FIG. 1 shows a conventional metal oxide transistor 101. The transistor comprises the elements of a gate 140 on a gate oxide 130, with isolation structures 150 The gate 140 has a physical gate width 170. A first source/drain region 110 and a second source/drain region 120 are formed in a substrate 100 adjacent the gate 140. The source/drain regions 110 and 120 are separated by a channel 165 in the substrate 100 that has a physical channel length 160. When evaluating a channel length in a transistor, an important measurement is called the effective channel length, or L_{eff} 180, which is a function of both the physical channel length 160, and the physical gate width 170 of the gate 140 controlling the channel 165. In FIG. 1, L_{eff} 180 is shown as a length somewhere between the physical gate width 170 and the physical channel length 160.

Also shown in FIG. 1 is an overlap region 190 which exists when the physical gate width 170 is larger than the physical channel length 160. Some overlap is needed to assist operation, but too much overlap in this region 190 causes parasitic capacitance effects that negatively affect device performance.

A processing method as shown in FIGS. 2a-2c has been employed to improve hot electron reliability at the bottom corners of the gate, adjacent to the source/drain regions. This method also has the effect of narrowing L_{eff}.

FIG. 2a shows a metal oxide transistor at an intermediate stage of fabrication. A gate oxide 210 is shown as deposited on top of a semiconductor substrate 200. A gate 220 has been formed on top of the gate oxide 210 and the mask 230 used to form the gate is shown still in place on top of the gate.

In FIG. 2b, the gate 220 has been re-oxidized, creating a first side oxide region 236, a second side oxide region 240, a first bottom oxide region 238, and a second bottom oxide region 242. The first and second side oxide regions 236 and 240 are converted from material in the gate 220 and create a new physical gate width 232. It is desirable to be able to control and narrow the physical gate width 232, because as discussed above, the physical gate width directly affects the L_{eff} of the channel in the transistor.

Likewise, the first and second bottom oxide regions 238 and 242 are converted from material in the gate 220. The bottom oxide regions 238 and 242 have an electrical effect on the transistor by changing an effective gate oxide thickness 234. The associated increase in effective gate oxide thickness due to the bottom oxide regions 238 and 242 is undesirable. A larger effective gate oxide thickness has the negative impact of slowing device operating times, and higher voltages are required to operate the gates. However, using this method, side oxide regions 236 and 240 cannot be formed without creating bottom oxide regions 238 and 242.

As shown in FIG. 2c, in the oxidizing process, oxygen is diffused into the gate 520 from the side to form the first side oxide region 236 as shown by arrows 244. Oxygen is also diffused through the gate oxide 210 and into the bottom of the gate 520 to form the first bottom oxide region 238 as shown by arrow 246.

What is needed is a method of forming a transistor that allows for controlled narrowing of the physical gate width 232 to improve L_{eff} without creating the undesirable increase in effective gate oxide thickness 234.

### SUMMARY OF THE INVENTION

An improved method of reducing transistor channel length is shown. The method shown solves the problems of the need for higher device operating speed, and the need for lower gate operating voltages, as well as other problems.

A gate dielectric is formed on a semiconductor substrate, and a barrier layer is coupled to the gate dielectric that inhibits diffusion of an oxidizing species. A gate is formed on top of the barrier layer. A physical gate width may be narrowed by converting a portion of the walls of the gate to a dielectric material to improve L_{eff}, without increasing an effective gate thickness.

The physical channel length may also be reduced, improving L_{eff} The reduction is made below a length set by the minimum lithographic feature size by forming source/drain region extensions. The source/drain extensions may be formed by ion implantation, which may be at an angle with respect to the surface of the substrate.

The gate material may be oxidized such that the sides of the gate are controllably consumed and converted to an oxide. The width of the conducting portion of the gate is therefore physically narrowed, and can be controllably narrowed to near the physical channel length, as narrowed by the source/drain extensions.

The combination of narrowing the physical channel length and narrowing the physical gate width results in an effective channel length L_{eff} that is more narrow than possible using lithography alone. A shorter effective channel length L_{eff} results in smaller transistor devices, higher operating speeds, and lower voltage necessary to operate the transistors.

The negative side effects of increasing effective gate thickness are eliminated through the use of a barrier layer. A diffusing material is used to convert the gate material to a dielectric material in the gate width narrowing process described above. The barrier layer is formed on a gate dielectric layer, wherein the barrier layer inhibits diffusion of the particular diffusing material. In this manner, the dielectric conversion by the diffusing material is confined to the sides of the gate, and conversion from beneath the gate, through the gate dielectric layer is eliminated.

Although specific embodiments have been described, it will be appreciated by those of ordinary skill in the art that any arrangement which is calculated to achieve the same purpose may be substituted for the specific embodiment shown. This application is intended to cover any adaptations or variations of the present invention. It is to be understood that the above summary is intended to be illustrative, and not restrictive. Combinations of the above embodiments, and other embodiments will be apparent to those of skill in the art upon reviewing the above description. The scope of the invention includes any other applications in which the above structures and fabrication methods are used. The scope of the invention should be determined with reference to the appended claims, along with the full scope of equivalents to which such claims are entitled.

### BRIEF DESCRIPTION OF THE DRAWINGS

FIG. 1 shows a conventional metal oxide transistor.

FIG. 2a. shows a metal oxide transistor in an intermediate stage of a fabrication process according to a prior method.

FIG. 2b. shows a metal oxide transistor in a further stage of a fabrication process according to a prior method.

FIG. 2c. shows a magnified view of a channel and source/drain region of the transistor from FIG. 2b.

FIG. 3a. shows a metal oxide transistor in an intermediate stage of a fabrication process according to the invention.

FIG. 3b. shows a metal oxide transistor in a further stage of a fabrication process according to the invention.

FIG. 3c. shows a metal oxide transistor in a further stage of a fabrication process according to the invention.

FIG. 3d. shows a magnified view of a channel and source/drain region of the transistor from FIG. 3c.

FIG. 4 shows a perspective drawing of a personal computer.

FIG. 5 shows a schematic drawing of a central processing unit.

FIG. 6 shows a schematic drawing of a DRAM memory device.

### DETAILED DESCRIPTION OF THE PREFERRED EMBODIMENTS

In the following detailed description of the invention, reference is made to the accompanying drawings which form a part hereof, and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention.

The term “horizontal” as used in this application is defined as a plane parallel to the conventional plane or surface of a wafer or substrate, regardless of the orientation of the wafer or substrate. The term “vertical” refers to a direction perpendicular to the horizonal as defined above. Prepositions, such as “on”, “side” (as in “sidewall”), “higher”, “lower”, “over” and “under” are defined with respect to the conventional plane or surface being on the top surface of the wafer or substrate, regardless of the orientation of the wafer or substrate.

The terms wafer and substrate used in the following description include any structure having an exposed surface with which to form the integrated circuit (IC) structure of the invention. The term substrate is understood to include semiconductor wafers. The term substrate is also used to refer to semiconductor structures during processing, and may include other layers that have been fabricated thereupon. Both wafer and substrate include doped and undoped semiconductors, epitaxial semiconductor layers supported by a base semiconductor or insulator, as well as other semiconductor structures well known to one skilled in the art. The term conductor is understood to include semiconductors, and the terms insulator or dielectric are defined to include any material that is less electrically conductive than the materials referred to as conductors. The following detailed description is, therefore, not to be taken in a limiting sense, and the scope of the present invention is defined only by the appended claims, along with the full scope of equivalents to which such claims are entitled.

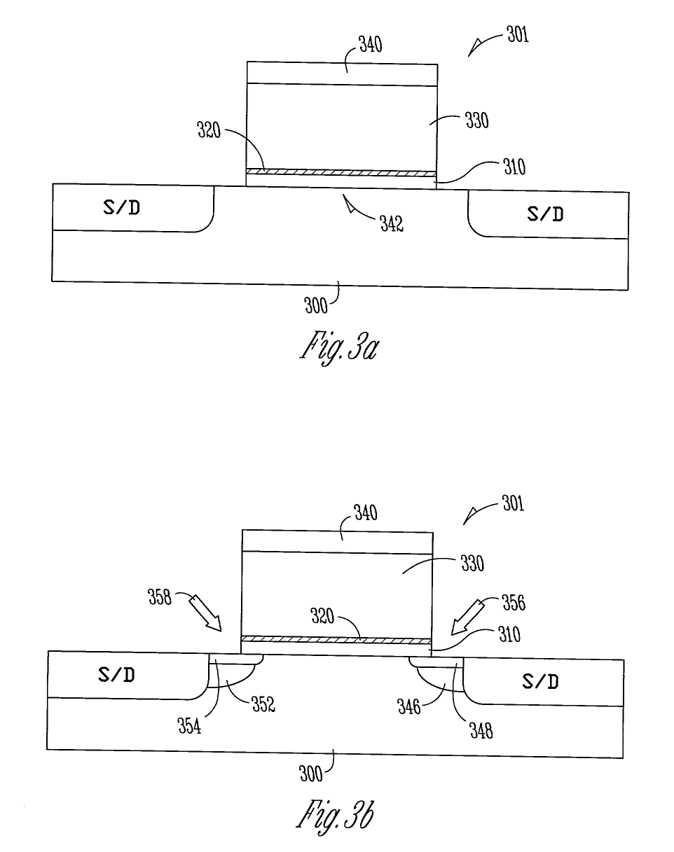

FIG. 3a shows a metal oxide semiconductor transistor 301 that may be included in a memory device such as a DRAM. The transistor 301 is shown in an intermediate stage of fabrication according to the invention. A semiconductor substrate 300 is shown with source/drain (S/D) regions formed in the substrate 300. A gate dielectric layer 310 has been formed on top of the substrate 300 in a channel region 342 between the two source/drain regions. The gate dielectric layer may be an oxide layer, or it may be another dielectric material of suitable resistivity. The substrate may be silicon, or an alternative semiconducting material such as gallium arsenide. The substrate may consist of a die of single crystal semiconductor or polycrystaline semiconductor, or the substrate may be a semiconducting layer formed on top of a base material (not shown).

A barrier layer 320 is shown, formed on top of the gate dielectric layer 310. The barrier layer may be a nitride layer or a composite oxide layer, or any equivalent layer that serves the purpose of inhibiting diffusion of a dielectric converting material. In this embodiment, the dielectric is an oxide, and the dielectric converting material is oxygen. One method of forming a nitride barrier layer is remote plasma nitridation. Another method of forming the barrier layer is direct plasma nitride processing. Still another method of forming the barrier layer is to use a composite gate and oxidation technique. In one embodiment, the barrier layer includes a thin silicon nitride (SiN) layer. One skilled in the art will recognize that more than one dielectric layer and more than one barrier layer may be used without departing from the scope of the invention.

Finally, in FIG. 3a, a gate 330 is shown on the barrier layer, with a masking layer 340 still on the gate 330. The gate may be composed of silicon or polysilicon, or a suitable semiconductor. In one embodiment, the gate 330 is doped.

FIG. 3b shows the formation of a first source/drain extension 348 and a second source/drain extension 354. The first source/drain extension 348 may be located adjacent to a first pocket implant region 346, and likewise the second source/drain extension 354 may be located adjacent to a second pocket implant region 352. The source/drain extensions 348 and 354 may be formed by an angled implant as shown by arrows 356 and 358 respectively. One skilled in the art will recognize that the source/drain extensions 348 and 354 may be formed at various stages in the fabrication of the transistor 301, and implanted at various angles without departing from the scope of the invention.

FIG. 3c shows the formation of a first side dielectric region 366 and a second side dielectric region 368. The side dielectric regions 366 and 368 may be oxide regions, and in one embodiment, they are formed by an oxidation process where oxygen consumes the semiconductor material of the gate 330 as oxygen diffuses into the gate 330. The side dielectric regions 366 and 368 are located on top of the barrier layer 320 and below the mask layer 340. As the material in the gate 330 is consumed, the side dielectric regions 366 and 368 define a new physical gate width 362. The process of creating the side dielectric regions 366 and 368 is a controlled process, and as a result, the physical gate width 362 can be adjusted to a high degree of accuracy. This is advantageous because the physical gate width affects the L_{eff} of the transistor 301.

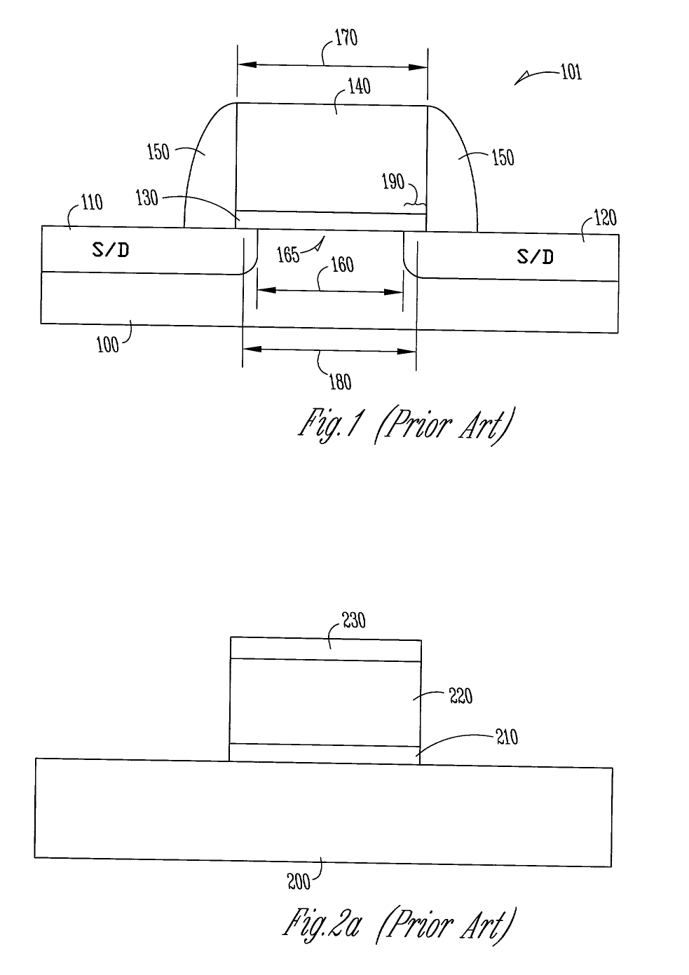

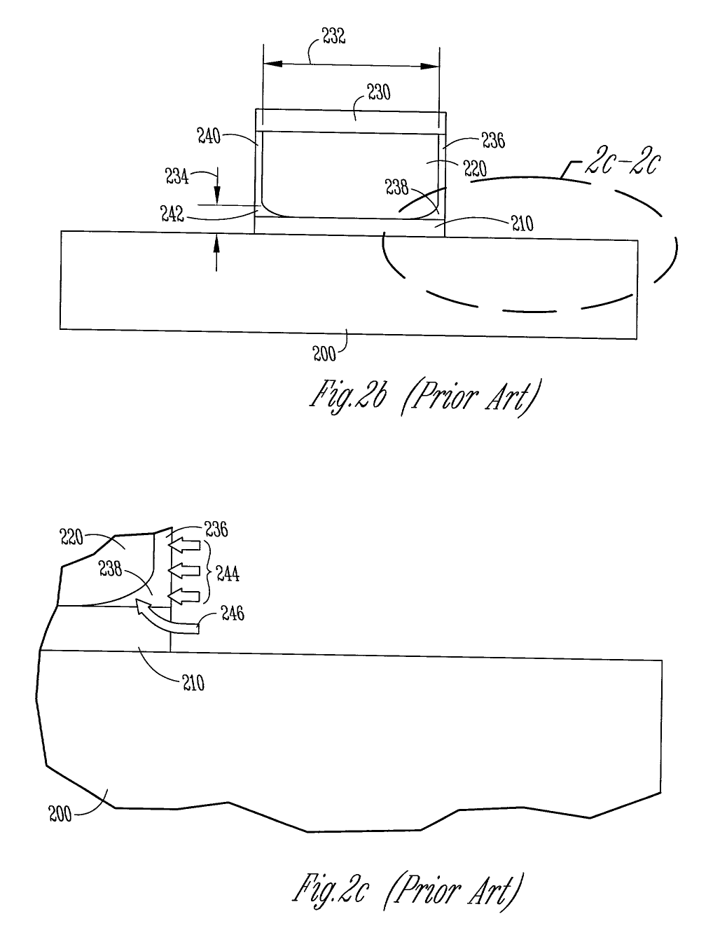

Using this process, an L_{eff} that is more narrow than a minimum lithographic feature size can be created at a given lithographic generation. The L_{eff} in this embodiment, created by this novel process is the same as the physical gate width 362, and is optimally close to but slightly larger than the physical channel length 360. A transistor 301 with these dimensions, the dimensions being smaller than a minimum lithographic feature size, can be uniquely achieved using the method shown. In addition, overlap regions 190 such as depicted in FIG. 1 are optimally reduced in this embodiment, through this novel process. The use of this process therefore allows the formation of gates and channels smaller than a minimum lithographic feature size without the negative parasitic capacitance effects caused by overlap regions.

Gates can be manufactured at a beginning width 364 that is as wide as the minimum lithographic feature size using the mask 340. A smaller physical channel length 360 of the channel region 342 can then be created by using the implanting step described above to create the source/drain extensions 348 and 354. Then, the physical gate width 362 can be adjusted from the beginning width 364 to a more narrow width that is closer to the physical channel length 360 and reduces or eliminates parasitic capacitance effects from the gate 330 overlapping the source/drain regions.

Further, as shown in FIG. 3d, the novel process of narrowing the channel L_{eff} of the transistor 301 eliminates any unwanted increase in an effective gate dielectric thickness 370. In this embodiment, the gate 330 is oxidized by oxygen atoms diffusing into the sides of the gate 330 as shown by arrows 372. The previous problem of bottom oxide regions being created is eliminated by the addition of the barrier layer 320. Oxygen may diffuse into the gate dielectric layer 310, but it is prohibited from diffusing into the bottom of the gate 330 by the barrier layer 320 as shown by arrow 374.

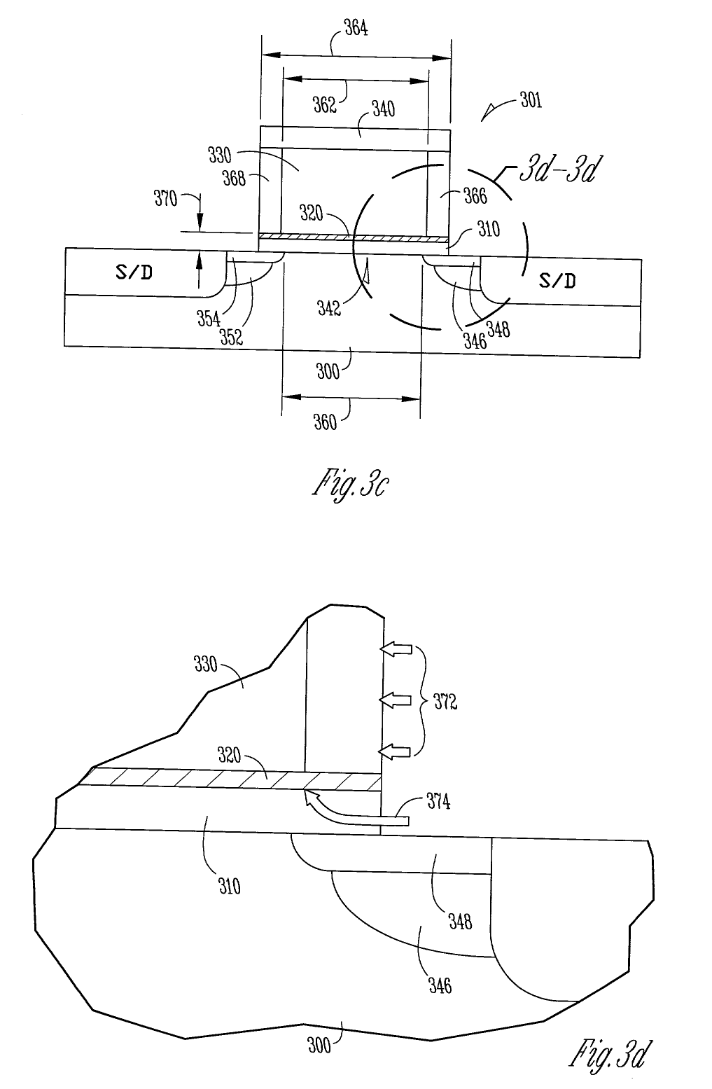

Transistors created by the methods described above may be implemented into memory devices and computing devices as shown in FIGS. 4-6 and described below. While specific types of memory devices and computing devices are shown below, it will be recognized by one skilled in the art that several types of memory devices and computing devices could utilize the invention.

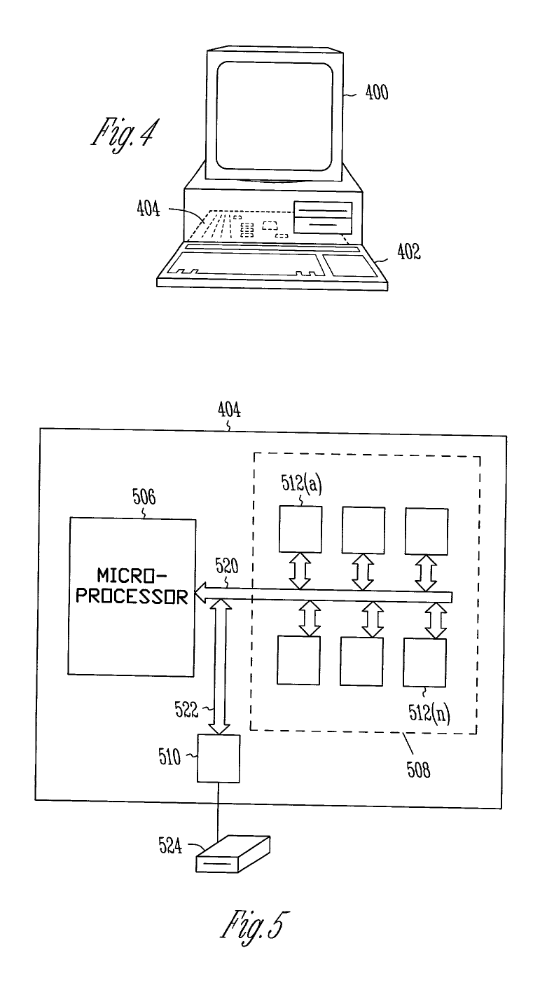

A personal computer, as shown in FIGS. 4 and 5, include a monitor 400, keyboard input 402 and a central processing unit 404. The processor unit typically includes microprocessor 506, memory bus circuit 508 having a plurality of memory slots 512(a-n), and other peripheral circuitry 510. Peripheral circuitry 510 permits various peripheral devices 524 to interface processor-memory bus 520 over input/output (I/O) bus 522.

Microprocessor 506 produces control and address signals to control the exchange of data between memory bus circuit 508 and microprocessor 506 and between memory bus circuit 508 and peripheral circuitry 510. This exchange of data is accomplished over high speed memory bus 520 and over high speed I/O bus 522.

Coupled to memory bus 520 are a plurality of memory slots 512(a-n) which receive memory devices well known to those skilled in the art. For example, single in-line memory modules (SIMMs) and dual in-line memory modules (DIMMs) may be used in the implementation of the present invention. Each type of integrated memory device has an associated communications speed which in turn limits the speed data can be read out of or written into memory bus circuit 508.

These memory devices can be produced in a variety of designs which provide different methods of reading from and writing to the dynamic memory cells of memory slots 512. One such method is the page mode operation. Page mode operations in a DRAM are defined by the method of accessing a row of a memory cell arrays and randomly accessing different columns of the array. Data stored at the row and column intersection can be read and output while that column is accessed. Page mode DRAMs require access steps which limit the communication speed of memory circuit 508. A typical communication speed using page mode a DRAM device is approximately 33 MHZ.

An alternate type of device is the extended data output (EDO) memory which allows data stored at a memory array address to be available as output after the addressed column has been closed. This memory can increase some communication speeds by allowing shorter access signals without reducing the time in which memory output data is available on memory bus 520. Other alternative types of devices include SDRAM, DDR SDRAM, SLDRAM and Direct RDRAM as well as others such as SRAM or Flash memories.

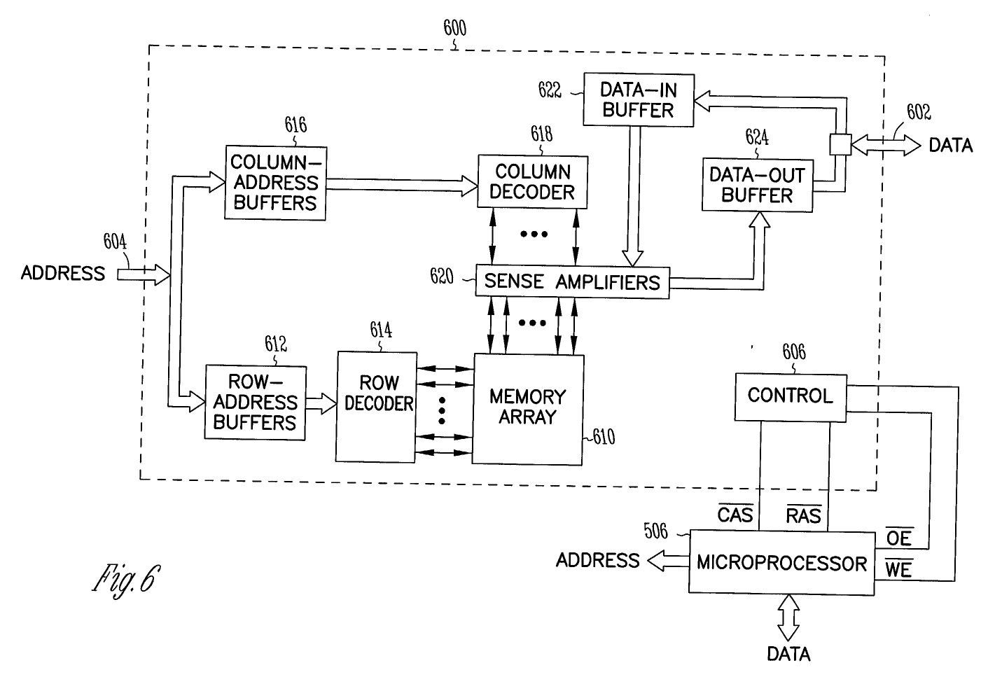

FIG. 6 is a block diagram of an illustrative DRAM device 600 compatible with memory slots 512(a-n). The description of DRAM 600 has been simplified for purposes of illustrating a DRAM memory device and is not intended to be a complete description of all the features of a DRAM. Those skilled in the art will recognize that a wide variety of memory devices may be used in the implementation of the present invention.

Control, address and data information provided over memory bus 520 is further represented by individual inputs to DRAM 600, as shown in FIG. 6. These individual representations are illustrated by data lines 602, address lines 604 and various discrete lines directed to control logic 606.

As is well known in the art, DRAM 600 includes memory array 610 which in turn comprises rows and columns of addressable memory cells. Each memory cell in a row is coupled to a common wordline. Additionally, each memory cell in a column is coupled to a common bitline. Each cell in memory array 610 includes a storage capacitor and an access transistor as is conventional in the art.

DRAM 600 interfaces with, for example, microprocessor 506 through address lines 604 and data lines 602. Alternatively, DRAM 600 may interface with a DRAM controller, a micro-controller, a chip set or other electronic system. Microprocessor 506 also provides a number of control signals to DRAM 600, including but not limited to, row and column address strobe signals RAS* and CAS*, write enable signal WE*, an output enable signal OE* and other conventional control signals.

The illustrative embodiments described herein concern electrical circuitry which uses voltage levels to represent binary logic states—namely, a “high” logic level and a “low” logic level. Further, electronic signals used by the various embodiments of the present invention are generally considered active when they are high. However, an asterisk (*) following the signal name in this application indicates that the signal is negative or inverse logic. Negative or inverse logic is considered active when the signal is low.

Row address buffer 612 and row decoder 614 receive and decode row addresses from row address signals provided on address lines 604 by microprocessor 506. Each unique row address corresponds to a row of cells in memory array 610. Row decoder 614 includes a wordline driver, an address decoder tree, and circuitry which translates a given row address received from row address buffers 612 and selectively activates the appropriate wordline of memory array 610 via the wordline drivers.

Column address buffer 616 and column decoder 618 receive and decode column address signals provided on address lines 604. Column decoder 618 also determines when a column is defective and the address of a replacement column. Column decoder 618 is coupled to sense amplifiers 620. Sense amplifiers 620 are coupled to complementary pairs of bitlines of memory array 610.

Sense amplifiers 620 are coupled to data-in buffer 622 and data-out buffer 624. Data-in buffers 622 and data-out buffers 624 are coupled to data lines 602. During a write operation, data lines 602 provide data to data-in buffer 622. Sense amplifier 620 receives data from data-in buffer 622 and stores the data in memory array 610 as a charge on a capacitor of a cell at an address specified on address lines 604.

During a read operation, DRAM 600 transfers data to microprocessor 506 from memory array 610. Complementary bitlines for the accessed cell are equilibrated during a precharge operation to a reference voltage provided by an equilibration circuit and a reference voltage supply. The charge stored in the accessed cell is then shared with the associated bitlines. A sense amplifier of sense amplifiers 620 detects and amplifies a difference in voltage between the complementary bitlines. The sense amplifier passes the amplified voltage to data-out buffer 624.

Control logic 606 is used to control the many available functions of DRAM 600. In addition, various control circuits and signals not detailed herein initiate and synchronize DRAM 600 operation as known to those skilled in the art. As stated above, the description of DRAM 600 has been simplified for purposes of illustrating the present invention and is not intended to be a complete description of all the features of a DRAM. Those skilled in the art will recognize that a wide variety of memory devices, including but not limited to, SDRAMs, SLDRAMs, RDRAMs and other DRAMs and SRAMs, VRAMs and EEPROMs, may be used in the implementation of the present invention. The DRAM implementation described herein is illustrative only and not intended to be exclusive or limiting.

### Conclusion

Thus an improved method of reducing transistor channel length is shown. The physical channel length is reduced below a length set by the minimum lithographic feature size by implanting source/drain region extensions. The physical gate width is then narrowed by oxidizing the walls of the gate. The combination of narrowing the physical channel length and narrowing the physical gate width results in an effective channel length L_{eff} that is more narrow than possible using lithography alone. The negative effects of increasing effective gate thickness are eliminated through the use of a barrier layer.

Although specific embodiments have been illustrated and described herein, it will be appreciated by those of ordinary skill in the art that any arrangement which is calculated to achieve the same purpose may be substituted for the specific embodiment shown. This application is intended to cover any adaptations or variations of the present invention. It is to be understood that the above description is intended to be illustrative, and not restrictive. Combinations of the above embodiments, and other embodiments will be apparent to those of skill in the art upon reviewing the above description. The scope of the invention includes any other applications in which the above structures and fabrication methods are used. The scope of the invention should be determined with reference to the appended claims, along with the full scope of equivalents to which such claims are entitled.

What is claimed is:

1. A method of reducing a channel length in a transistor, comprising:
forming a gate dielectric layer on a semiconductor substrate;
coupling a barrier layer to the gate dielectric layer, wherein the barrier layer prevents oxide undergrowth;
forming a gate on top of the barrier layer, the gate having sides, and an effective channel length defined by the sides; and
oxidizing the gate wherein a portion of the sides of the gate are converted to an oxide and an effective channel length of the gate is reduced.

2. The method of claim 1, wherein coupling a barrier layer to the gate dielectric layer comprises coupling a silicon nitride (SiN) layer to the gate dielectric layer.

3. The method of claim 2, wherein coupling a silicon nitride (SiN) layer to the gate dielectric layer comprises remote plasma nitride processing the gate dielectric layer to form a silicon nitride (SiN) layer.

4. The method of claim 2, wherein coupling a silicon nitride (SiN) layer to the gate dielectric layer comprises composite oxidation processing the gate dielectric layer to form a silicon nitride (SiN) layer.

5. The method of claim 1, wherein forming a gate dielectric layer on a semiconductor substrate comprises forming a gate oxide layer on a semiconductor substrate.

6. The method of claim 1, wherein forming a gate dielectric layer on a semiconductor substrate comprises forming a gate dielectric layer on a silicon substrate.

7. A method of forming a transistor, comprising:
forming a first source/drain region and a second source/drain region in a semiconductor substrate;
forming a gate dielectric layer on the semiconductor substrate;
coupling a barrier layer to the gate dielectric layer, wherein the barrier layer prevents oxide undergrowth;
forming a gate on top of the barrier layer, the gate having sides, and an effective channel length defined by the sides; and
oxidizing the gate wherein a portion of the sides of the gate are converted to an oxide and an effective channel length of the gate is reduced.

8. The method of claim 7, wherein coupling a barrier layer to the gate dielectric layer comprises coupling a silicon nitride (SiN) layer to the gate dielectric layer.

9. The method of claim 8, wherein coupling a silicon nitride (SiN) layer to the gate dielectric layer comprises remote plasma nitride processing the gate dielectric layer to form a silicon nitride (SiN) layer.

10. The method of claim 8, wherein coupling a silicon nitride (SiN) layer to the gate dielectric layer comprises composite oxidation processing the gate dielectric layer to form a silicon nitride (SiN) layer.

11. The method of claim 7, wherein forming a gate dielectric layer on a semiconductor substrate comprises forming a gate oxide layer on a semiconductor substrate.

12. The method of claim 7, wherein forming a gate dielectric layer on a semiconductor substrate comprises forming a gate dielectric layer on a silicon substrate.

13. The method of claim 7, further including forming a first source/drain extension adjacent the first source/drain region and a second source/drain extension adjacent the second source/drain region.

14. A method of forming a transistor, comprising:
forming a first source/drain region and a second source/drain region in a semiconductor substrate;
forming a gate dielectric layer on the semiconductor substrate;
coupling a nitride layer to the gate dielectric layer, wherein the nitride layer prevents oxide undergrowth;
forming a gate on top of the nitride layer, the gate having sides, and an effective channel length defined by the sides; and
oxidizing the gate wherein a portion of the sides of the gate are converted to an oxide and an effective channel length of the gate is reduced.

15. The method of claim 14, wherein coupling a nitride layer to the gate dielectric layer comprises coupling a silicon nitride (SiN) layer to the gate dielectric layer.

16. The method of claim 15, wherein coupling a silicon nitride (SiN) layer to the gate dielectric layer comprises remote plasma nitride processing the gate dielectric layer to form a silicon nitride (SiN) layer.

17. The method of claim 15, wherein coupling a silicon nitride (SiN) layer to the gate dielectric layer comprises composite oxidation processing the gate dielectric layer to form a silicon nitride (SiN) layer.

18. The method of claim 14, wherein forming a gate dielectric layer on a semiconductor substrate comprises forming a gate oxide layer on a semiconductor substrate.

19. The method of claim 14, wherein forming a gate dielectric layer on a semiconductor substrate comprises forming a gate dielectric layer on a silicon substrate.

20. The method of claim 14, further including forming a first source/drain extension adjacent the first source/drain region and a second source/drain extension adjacent the second source/drain region.

21. A method of forming an integrated circuit, comprising:
forming a number of transistors on a semiconductor substrate, wherein forming at least one of the number of transistors comprises:
forming a first source/drain region and a second source/drain region in the semiconductor substrate;
forming a gate dielectric layer on the semiconductor substrate;
coupling a barrier layer to the gate dielectric layer, wherein the barrier layer prevents oxide undergrowth;
forming a gate on top of the barrier layer, the gate having sides, and an effective channel length defined by the sides;
oxidizing the gate wherein a portion of the sides of the gate are converted to an oxide and an effective channel length of the gate is reduced; and
electrically connecting the number of transistors.

22. The method of claim 21, wherein coupling a barrier layer to the gate dielectric layer comprises coupling a silicon nitride (SiN) layer to the gate dielectric layer.

23. The method of claim 22, wherein coupling a silicon nitride (SiN) layer to the gate dielectric layer comprises remote plasma nitride processing the gate dielectric layer to form a silicon nitride (SiN) layer.

24. The method of claim 22, wherein coupling a silicon nitride (SiN) layer to the gate dielectric layer comprises composite oxidation processing the gate dielectric layer to form a silicon nitride (SiN) layer.

25. The method of claim 21, wherein forming a gate dielectric layer on a semiconductor substrate comprises forming a gate oxide layer on a semiconductor substrate.

26. The method of claim 21, wherein forming a gate dielectric layer on a semiconductor substrate comprises forming a gate dielectric layer on a silicon substrate.

27. A method of forming an integrated circuit, comprising:
forming a number of transistors on a semiconductor substrate, wherein forming at least one of the number of transistors comprises:
forming a first source/drain region and a second source/drain region in the semiconductor substrate;
forming a first source/drain extension adjacent the first source/drain region and a second source/drain extension adjacent the second source/drain region;
forming a gate dielectric layer on the semiconductor substrate;
coupling a barrier layer to the gate dielectric layer, wherein the barrier layer prevents oxide undergrowth;
forming a gate on top of the barrier layer, the gate having sides, and an effective channel length defined by the sides;
oxidizing the gate wherein a portion of the sides of the gate are converted to an oxide and an effective channel length of the gate is reduced; and
electrically connecting the number of transistors.

28. A method of forming an integrated circuit, comprising:
forming a number of transistors on a semiconductor substrate, wherein forming at least one of the number of transistors comprises:
forming a first source/drain region and a second source/drain region in the semiconductor substrate;
forming a gate dielectric layer on the semiconductor substrate;
coupling a nitride layer to the gate dielectric layer, wherein the nitride layer prevents oxide undergrowth;
forming a gate on top of the nitride layer, the gate having sides, and an effective channel length defined by the sides;
oxidizing the gate wherein a portion of the sides of the gate are converted to an oxide and an effective channel length of the gate is reduced; and
electrically connecting the number of transistors.

29. The method of claim 28, wherein coupling a nitride layer to the gate dielectric layer comprises coupling a silicon nitride (SiN) layer to the gate dielectric layer.

30. The method of claim 29, wherein coupling a silicon nitride (SiN) layer to the gate dielectric layer comprises remote plasma nitride processing the gate dielectric layer to form a silicon nitride (SiN) layer.

31. The method of claim 29, wherein coupling a silicon nitride (SiN) layer to the gate dielectric layer comprises composite oxidation processing the gate dielectric layer to form a silicon nitride (SiN) layer.

32. The method of claim 28, wherein forming a gate dielectric layer on a semiconductor substrate comprises forming a gate oxide layer on a semiconductor substrate.

33. The method of claim 28, wherein forming a gate dielectric layer on a semiconductor substrate comprises forming a gate dielectric layer on a silicon substrate.

34. The method of claim 28, further including forming a first source/drain extension adjacent the first source/drain region and a second source/drain extension adjacent the second source/drain region.

35. A method of forming a memory device, comprising:
forming a number of transistors on a semiconductor substrate, comprising:
forming a first source/drain region and a second source drain region in the semiconductor substrate;
forming a gate dielectric layer on the semiconductor substrate;
coupling a barrier layer to the gate dielectric layer, wherein the barrier layer prevents oxide undergrowth;
forming a gate on top of the barrier layer, the gate having sides, and an effective channel length defined by the sides;
oxidizing the gate wherein a portion of the sides of the gate are converted to an oxide and an effective channel length of the gate is reduced;
forming a number of wordlines coupled to the gates of the number of transistors; and
forming a number of wordlines coupled to the first source/drain region of the number of transistors.

36. The method of claim 35, wherein coupling a barrier layer to the gate dielectric layer comprises coupling a silicon nitride (SiN) layer to the gate dielectric layer.

37. The method of claim 36, wherein coupling a silicon nitride (SiN) layer to the gate dielectric layer comprises remote plasma nitride processing the gate dielectric layer to form a silicon nitride (SiN) layer.

38. The method of claim 36, wherein coupling a silicon nitride (SiN) layer to the gate dielectric layer comprises composite oxidation processing the gate dielectric layer to form a silicon nitride (SiN) layer.

39. The method of claim 35, wherein forming a gate dielectric layer on a semiconductor substrate comprises forming a gate oxide layer on a semiconductor substrate.

40. The method of claim 35, wherein forming a gate dielectric layer on a semiconductor substrate comprises forming a gate dielectric layer on a silicon substrate.

41. A method of forming a memory device, comprising:
forming a number of transistors on a semiconductor substrate, comprising:
forming a first source/drain region and a second source drain region in the semiconductor substrate;
forming a first source/drain extension adjacent the first source/drain region and a second source/drain extension adjacent the second source/drain region;
forming a gate dielectric layer on the semiconductor substrate;
coupling a barrier layer to the gate dielectric layer, wherein the barrier layer prevents oxide undergrowth;
forming a gate on top of the barrier layer, the gate having sides, and an effective channel length defined by the sides;
oxidizing the gate wherein a portion of the sides of the gate are converted to an oxide and an effective channel length of the gate is reduced;
forming a number of wordlines coupled to the gates of the number of transistors; and
forming a number of wordlines coupled to the first source/drain region of the number of transistors.

42. A method of making an information handling system, comprising:
providing a processor chip;
forming a semiconductor memory device, comprising:
forming a number of transistors on a semiconductor substrate, comprising:
forming a first source/drain region and a second source/drain region in the semiconductor substrate;
forming a gate dielectric layer on the semiconductor substrate;
coupling a barrier layer to the gate dielectric layer, wherein the barrier layer prevents oxide undergrowth;
forming a gate on top of the barrier layer, the gate having sides, and an effective channel length defined by the sides;
oxidizing the gate wherein a portion of the sides of the gate are converted to an oxide and an effective channel length of the gate is reduced;
forming a number of wordlines coupled to the gates of the number of transistors;
forming a number of wordlines coupled to the first source/drain region of the number of transistors; and
coupling the processor chip to the semiconductor memory device with a system bus.

43. The method of claim 42, wherein coupling a barrier layer to the gate dielectric layer comprises coupling a silicon nitride (SiN) layer to the gate dielectric layer.

44. The method of claim 43, wherein coupling a silicon nitride (SiN) layer to the gate dielectric layer comprises remote plasma nitride processing the gate dielectric layer to form a silicon nitride (SiN) layer.

45. The method of claim 43, wherein coupling a silicon nitride (SiN) layer to the gate dielectric layer comprises composite oxidation processing the gate dielectric layer to form a silicon nitride (SiN) layer.

46. The method of claim 42, wherein forming a gate dielectric layer on a semiconductor substrate comprises forming a gate oxide layer on a semiconductor substrate.

47. The method of claim 42, wherein forming a gate dielectric layer on a semiconductor substrate comprises forming a gate dielectric layer on a silicon substrate.

48. The method of claim 42, further including forming a first source/drain extension adjacent the first source/drain region and a second source/drain extension adjacent the second source/drain region.

49. A transistor comprising:
a first source/drain region and a second source/drain region disposed in a substrate;
a channel region between the first source/drain region and the second source/drain region;
a gate dielectric layer coupled to the channel region;
a barrier layer coupled to the gate dielectric layer, wherein the barrier layer prevents oxide undergrowth;
a gate formed from a gate material coupled to the barrier layer; and
a side dielectric region converted from a portion of the gate material, the side dielectric region having a thickness at a top of the gate that is substantially the same as a thickness at a bottom of the gate.

50. The transistor of claim 49, wherein the barrier layer comprises a nitrided layer.

51. The transistor of claim 50, wherein the nitrided layer comprises silicon nitride.

52. The transistor of claim 50, wherein the side dielectric region comprises silicon dioxide.

53. The transistor of claim 50, further comprising a source/drain extension operatively connected to the first source/drain region extending into the channel region.

54. A transistor formed by the following process:
forming a first source/drain region and a second source/drain region in a semiconductor substrate;
forming a gate dielectric layer on the semiconductor substrate;
coupling a barrier layer to the gate dielectric layer, wherein the barrier layer prevents oxide undergrowth;
forming a gate on top of the barrier layer, the gate having sides, and an effective channel length defined by the sides; and
oxidizing the gate wherein a portion of the sides of the gate are converted to an oxide and an effective channel length of the gate is reduced.
